(19) United States
(12) Patent Application Publication
(10) Pub. No.: US 2019/0019814 A1
(43) Pub. Date: Jan. 17, 2019

(54) DISPLAY SUBSTRATE, METHOD FOR FABRICATING THE SAME, DISPLAY PANEL

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Xianxue DUAN, Beijing (CN); Kui GONG, Beijing (CN); Hefei LI, Beijing (CN); Jilong LI, Beijing (CN); Hui AN, Beijing (CN); Biliang DONG, Beijing (CN); Chengcheng WANG, Beijing (CN)

(21) Appl. No.: 15/750,477

(22) PCT Filed: Jun. 16, 2017
(86) PCT No.: PCT/CN2017/088645

§ 371 Date: Feb. 5, 2018

(30) Foreign Application Priority Data
Aug. 12, 2016 (CN) 201610666482.3

(51) Int. Cl. H01L 27/12

(52) U.S. Cl. CPC H01L 27/1222; H01L 27/1237; H01L 29/78663; H01L 27/1262; H01L 27/127

(57) ABSTRACT

A display substrate, a method for fabricating the same, and a display panel are disclosed. The method comprises forming a TFT on a substrate. The TFT comprises a gate, a gate insulating layer, an active layer, an ohmic contact layer, a source and a drain which are formed on the substrate in sequence. After forming the active layer, and prior to forming the ohmic contact layer, the method comprises forming a first pattern in a non-TFT region. The first pattern in the non-TFT region covers the gate insulating layer.

### RELATED APPLICATIONS

The present application claims the benefit of Chinese Patent Application No. 201610666482.3, filed on Aug. 12, 2016, the entire disclosure of which is incorporated herein by reference.

### TECHNICAL FIELD

The present disclosure relates to the field of display technology, and particularly to a display substrate, a method for fabricating the same, and a display panel.

### BACKGROUND

A thin film transistor (TFT) acts as a switching control unit, and has been widely applied in the display field. A TFT array substrate comprises a display region in which a plurality of pixel units are arranged in an array. Each of the pixel units is provided with a TFT switch for controlling the pixel unit.

An amorphous silicon TFT has excellent performance, a mature process and low cost, so that it has been applied extensively. In the amorphous silicon TFT, an active layer comprises an amorphous silicon active layer and an n⁺ amorphous silicon ohmic contact layer. Forming the active layer generally involves two etching processes. A first etching process is used to form a silicon island pattern of the active layer, and a second etch process is used to etch gaps among n⁺ amorphous silicon ohmic contact layers.

### SUMMARY

Embodiment of the present disclosure provide a display substrate, a method for fabricating the same, and a display panel, which can alleviate or solve one or more problems in the art.

In a first aspect, it is provided a method for fabricating a display substrate, comprising forming a TFT on a substrate. Forming the TFT comprises forming a gate, a gate insulating layer, an active layer, an ohmic contact layer, a source and a drain on the substrate in sequence. After forming the active layer, and prior to forming the ohmic contact layer, the method further comprises forming a first pattern in a non-TFT region. The first pattern in the non-TFT region is configured to cover the gate insulating layer.

For example, the method further comprises: forming a second pattern in a channel region of the active layer by using a same insulating material as the first pattern and at a same time as forming the first pattern in the non-TFT region.

For example, the method comprises: at a same time as forming the ohmic contact layer, partially etching the second pattern to partially retain a thickness of the second pattern and form a protection insulating layer pattern.

For example, the protection insulating layer pattern has a thickness of 5-15 nm.

For example, forming the ohmic contact layer, the protection insulating layer pattern, the source and the drain comprises:

forming the first pattern and the second pattern on the substrate on which the active layer has been formed;

forming an ohmic contact transitional pattern on the substrate on which the first pattern and the second pattern have been formed, wherein the ohmic contact transitional pattern has a same shape as the active layer; and

forming the source and the drain on the substrate on which the ohmic contact transitional pattern has been formed, and etching the ohmic contact transitional pattern, the first pattern and the second pattern to form the ohmic contact layer and the protection insulating layer pattern.

For example, the first pattern is etched away. Alternatively, the first pattern is etched to a thickness smaller than that of the protection insulating layer pattern.

For example, after forming the first pattern and the second pattern, the method further comprises:

forming an ohmic contact transitional pattern on the substrate on which the first pattern and the second pattern have been formed, wherein the ohmic contact transitional pattern is arranged in a source region and a drain region of the TFT region; and

forming the source and the drain on the substrate on which the ohmic contact transitional pattern has been formed.

For example, after forming the source and the drain, the method further comprises: etching the first pattern and the second pattern to have a same thickness.

For example, both the first pattern and the second pattern are etched away.

For example, the active layer is formed by amorphous silicon, and the ohmic contact layer is formed by n⁺ amorphous silicon.

For example, the insulating material comprises at least one of SiO₂, SiₓN_{y}, and SiOₓN_{y}.

For example, the ohmic contact transitional pattern, the first pattern and the second pattern are etched by dry etching in a mixture comprising SF₆ and O₂, Cl₂ and O₂, or CF₄ and O₂.

In a second aspect, it is provided a display substrate, comprising a TFT which is arranged on a substrate. The TFT comprises a gate, a gate insulating layer, an active layer, an ohmic contact layer, a source and a drain which are arranged on the substrate in sequence. The TFT comprises a protection insulating layer pattern which is arranged on a side of the active layer away from the substrate, and is arranged in a channel region.

For example, the protection insulating layer pattern has a thickness of 5-15 nm.

For example, the active layer is formed by amorphous silicon, and the ohmic contact layer is formed by n⁺ amorphous silicon.

For example, the protection insulating layer pattern comprises at least one of SiO₂, SiₓN_{y}, and SiOₓN_{y}.

For example, the display substrate is an array substrate.

In a third aspect, it is provided a display panel, comprising the display substrate as described above.

### BRIEF DESCRIPTION OF THE DRAWINGS

In order to explain the technical solutions in the embodiments of the present disclosure or the prior art more clearly, the drawings to be used in the description of the embodiments or the prior art will be introduced briefly in the following. Apparently, the drawings described below are only some embodiments of the present disclosure.

FIG. 1a is a structural view for illustrating a display substrate in an embodiment of the present disclosure;

FIG. 1b is a structural view for illustrating a display substrate in an embodiment of the present disclosure;

FIG. 2 is a structural view for illustrating a display substrate in an embodiment of the present disclosure;

FIGS. 3, 4, 5, 6, 7, 8 are views for illustrating a process for fabricating a display substrate in an embodiment of the present disclosure;

FIGS. 9 and 10 are views for illustrating a process for fabricating a display substrate in an embodiment of the present disclosure;

FIG. 11 is a view for illustrating a process for fabricating a display substrate in an embodiment of the present disclosure;

FIG. 12 is a view for illustrating a process for fabricating display substrate in an embodiment of the present disclosure; and

FIG. 13 is a structural view for illustrating an array display substrate in an embodiment of the present disclosure.

### DETAILED DESCRIPTION OF EMBODIMENTS

The display substrate, the method for fabricating the same, the display panel, and the display apparatus in embodiments of the present disclosure will be described in detail hereinafter with reference to the accompanying drawing.

Reference numerals: 01 substrate; 02 TFT; 11 gate; 12 gate insulating layer; 13 amorphous silicon active layer; 14 protection insulating layer; 141 first pattern; 142 second pattern; 143 protection insulating layer pattern; 15 n⁺ amorphous silicon ohmic contact layer; 151 n⁺ amorphous silicon film; 152 n⁺ amorphous silicon transitional pattern; 16 source; 17 drain; 18 photoresist; 181 retained portion of photoresist; 19 pixel electrode; 30 non-TFT region.

During forming an ohmic contact layer of n⁺ amorphous silicon, since shielding is absent over the gate insulating layer, the gate insulating layer generally has a reduced thickness in the non-TFT region, which will damage the gate insulating layer. For instance, when the thickness of the active layer is etched by 100 nm during a second etching, the thickness of the gate insulating layer generally is reduced by 80 nm. It is one of the objectives of embodiments of the present disclosure to alleviate or eliminate the damage to the gate insulating layer during forming ohmic contact layer.

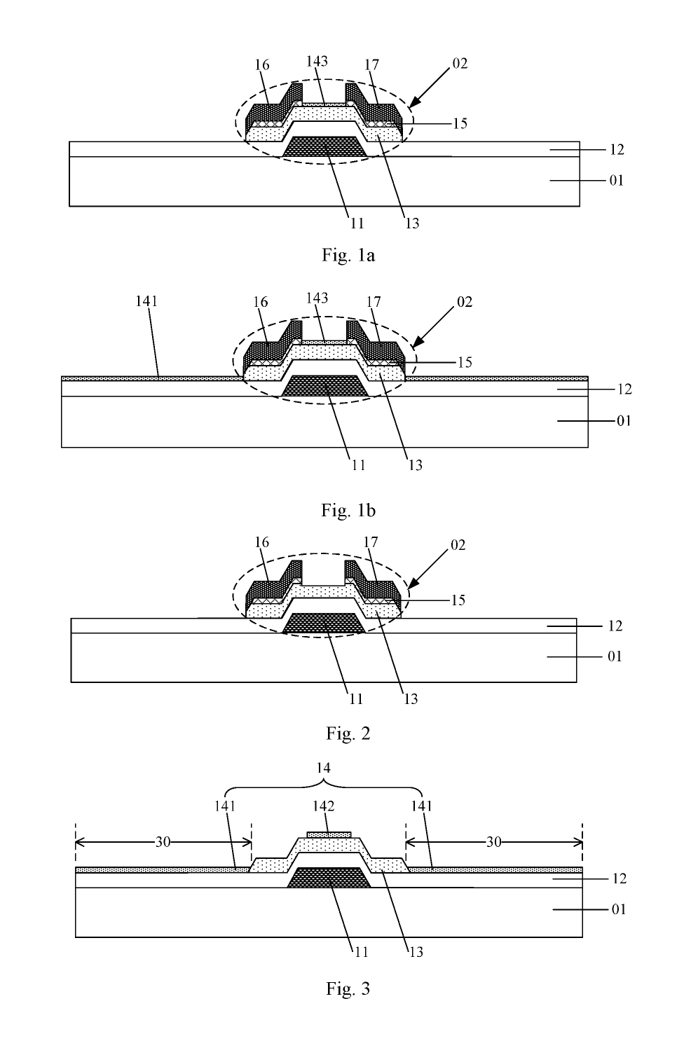

Embodiments of the present disclosure provide a method for fabricating a display substrate. As shown in FIG. 1a, FIG. 1b, and FIG. 2, the method comprises forming a TFT 02 on a substrate 01. The TFT 02 comprises a gate 11, a gate insulating layer 12, an amorphous silicon active layer 13, an n⁺ amorphous silicon ohmic contact layer 15, a source 16, and a drain 17, which are formed on the substrate 01 in sequence.

As shown in FIG. 3, after forming the amorphous silicon active layer 13, and prior to forming the n⁺ amorphous silicon ohmic contact layer 15, the method further comprises forming a protection insulating layer 14. The protection insulating layer 14 comprises a first pattern 141 in a non-TFT region 30. The first pattern 141 covers the gate insulating layer 12 in the non-TFT region 30.

In the TFT with the configuration as shown above, a leakage current mainly comprises: a first leakage current between the source and the drain, and a second leakage current consisting of a leakage current between the gate and the source and a leakage current between the gate and the drain. When the gate insulating layer at sides of the amorphous silicon active layer provides a poor coverage or the gate insulating layer is relatively thin, a large parasitic capacitance is developed between the gate and the source as well as between the gate and the drain. As a result, the second leakage current is large, and the leakage current of the TFT accordingly is large. According to embodiments of the present disclosure, since the first pattern 141 is formed in the non-TFT region 30 and covers the gate insulating layer 12, the gate insulating layer 12 at sides of the amorphous silicon active layer 13 provides good coverage, and the thickness of the gate insulating layer 12 is retained. Therefore, the parasitic capacitance between the gate 11 and the source 16 as well as between the gate 11 and the drain 17 is small. As a result, the second leakage current is small, and the leakage current of the TFT is small.

In embodiments of the present disclosure, the method further comprises: at a same time forming the first pattern 141 in the non-TFT region 30, forming a second pattern 142 in a channel region of the active layer 13 by using a same insulating material as the first pattern. The term “channel region” as used herein refers to a region between a source region and a drain region in a TFT region.

In embodiments of the present disclosure, the protection insulating layer 14 for example can be made from any suitable material which does not affect the channel region.

In embodiments of the present disclosure, the first pattern 141 of the protection insulating layer 14 is retained or removed. In an embodiment, only some thickness of the first pattern 141 is retained. In another embodiment, all thickness of the first pattern 141 is retained.

In embodiments of the present disclosure, the second pattern 142 of the protection insulating layer 14 is retained or removed. In an embodiment, only some thickness of the second pattern 142 is retained. In another embodiment, all thickness of the second pattern 142 is retained.

In embodiments of the present disclosure, when both the first pattern 141 and the second pattern 142 are removed, they can be removed at a same time.

In embodiments of the present disclosure, during the process for fabricating the display substrate, in case it is required to remove the first pattern 141, it is not intended to limit the step in which the first pattern 141 is removed, provided that the damage to the gate insulating layer 12 is avoided during the steps after forming the gate insulating layer 12.

Although the following embodiments are described by taking the active layer 13 of amorphous silicon and the ohmic contact layer 15 of n⁺ amorphous silicon as an example, embodiments of the present disclosure are not limited in terms of materials for the active layer and the ohmic contact layer.

It is noted that, embodiments of the present disclosure and all of the accompanying drawings are presented only for purpose of describing structures relevant with the inventive concept of the present disclosure, and irrelevant structures are not illustrated or partially illustrated.

Embodiments of the present disclosure provide a method for fabricating a display substrate. After forming the amorphous silicon active layer 13, and prior to forming the n⁺ amorphous silicon ohmic contact layer 15, the protection insulating layer 14 comprising the first pattern 141 in the non-TFT region 30 and the second pattern 142 in the channel region is formed. During forming the n⁺ amorphous silicon ohmic contact layer 15, the protection insulating layer 14 keeps the gate insulating layer 12 intact, the damage to the gate insulating layer 12 is avoided, and the performance of the display substrate is ensured. Since the protection insulating layer 14 is made from an insulating material, pollution to the channel region of the amorphous silicon active layer 13 (i.e., a portion of the amorphous silicon active layer 13 which correspond sto a gap between the source 16 and the drain 17) is avoided, so that the performance of the TFT 02 is ensured.

For example, as shown in FIG. 1a and FIG. 1b, at a same time as the n⁺ amorphous silicon ohmic contact layer 15 is formed, the second pattern 142 is partially etched, so that the second pattern 142 with a remaining thickness forms a protection insulating layer pattern 143.

Here, the first pattern 141 and the second pattern 142 comprise a same material and have a same thickness, and the n⁺ amorphous silicon film is directly formed on the first pattern 141 and the second pattern 142. Thus, at a same time as the second pattern 142 is etched, the first pattern 141 will also be etched. On basis of this, embodiments of the present disclosure are not limited to the case in which the first pattern 141 is completely removed (FIG. 1a) or the case in which the first pattern 141 is partially retained (FIG. 1b).

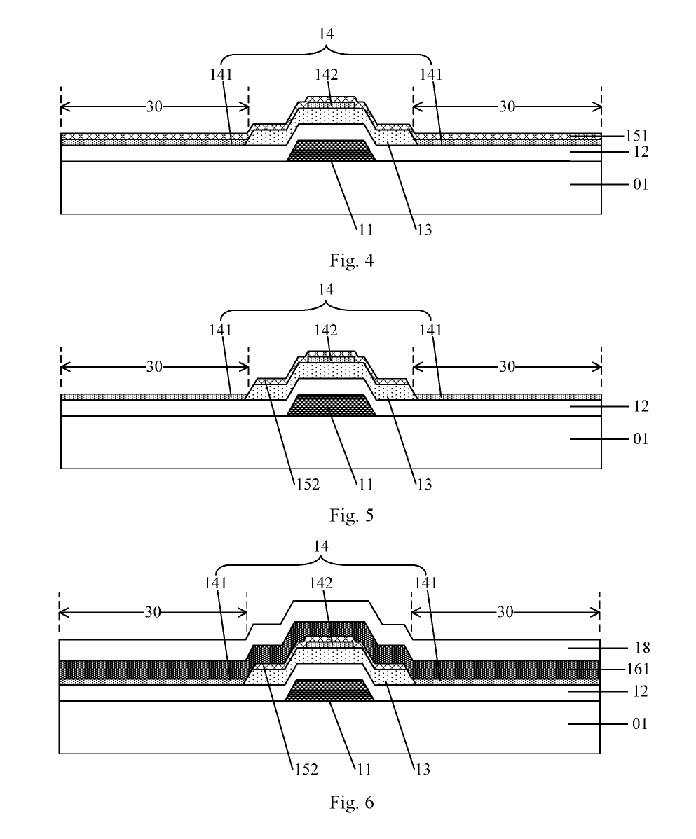

As an example, as shown in FIG. 4-8, at a same time as the n⁺ amorphous silicon ohmic contact layer 15 is formed, the first pattern 141 is removed, and a thickness of the second pattern 142 is retained, so that the second pattern 142 with the remaining thickness forms the protection insulating layer pattern 143.

It is noted that, since the first pattern 141 and the second pattern 142 comprise a same material and have a same thickness, for purpose of completely removing the first pattern 141 while partially retaining the second pattern 142, it is required that, prior to forming the n⁺ amorphous silicon ohmic contact layer 15 by etching, there is no n⁺ amorphous silicon film on the first pattern 141 or the n⁺ amorphous silicon film on the first pattern 141 has a thickness smaller than that of the n⁺ amorphous silicon film on the second pattern 142. On basis of this, it is further required to ensure that the n⁺ amorphous silicon can be etched in a same etching environment in which the material of the first pattern 141 and the second pattern 142 is etched.

In embodiments of the present disclosure, the protection insulating layer pattern 143 is formed on the channel region of the amorphous silicon active layer 13, so that the channel is prevented from being polluted by external electrically conductive particles, and the leakage current of the TFT 02 is reduced. The second pattern 142 is partially etched, so that electrically conductive particles accumulated on the surface of the second pattern 142 is prevented from penetrating the channel.

For example, the protection insulating layer pattern 143 has a thickness of 5-15 nm.

In embodiments of the present disclosure, the protection insulating layer pattern 143 is set to have a thickness of 5-15 nm. On one hand, this thickness is sufficient to prevent external electrically conductive particles from polluting the channel. On the other hand, the thickness of 5-15 nm is negligible, and thus avoids effects on an overall thickness of the display substrate.

The method for fabricating a display substrate will be described hereinafter with reference to a specific embodiment. As shown in FIG. 11, forming the display substrate for example comprises the following steps.

S10, as shown in FIG. 3, the gate 11 and the gate insulating layer 12 are formed on the substrate 01 in sequence.

In particular, a metal film with a thickness of 100 nm-700 nm is formed on the substrate 01 by a magnetron sputtering method. For example, a metal film with a thickness about 300 nm is formed. The metal film generally comprises metals such as Mo, Al, Al—Ni alloy, Mo—W alloy, Cr, or Cu, or a combination thereof. Then, the gate 11 is formed in the TFT region of the display substrate (i.e., a region between two non-TFT regions 30 in FIG. 3), by patterning processes comprising exposure with a mask, development, etching, and lifting off.

Of course, in case the display substrate is an array substrate, for example a gate line is formed at a same time as forming the gate 11.

Furthermore, an insulating film with a thickness of 100 nm-600 nm is deposited on the display substrate on which the gate 11 has been formed, by plasma enhanced chemical vapor deposition (PECVD). The insulating film generally comprises silicon nitride, silicon oxide, silicon oxynitride, or the like. For example, the gate insulating layer 12 of silicon nitride with a thickness of about 400 nm is formed.

It is noted that, prior to forming the metal film, the substrate 01 for example is cleaned in advance.

S11, as shown in FIG. 3, the active layer 13 of e.g. amorphous silicon is formed on the structure resulting from S10.

In particular, an amorphous silicon film with a thickness of 100 nm-600 nm is deposited by PECVD on the substrate 01 on which the gate insulating layer 12 has been formed. For example, an amorphous silicon film with a thickness about 200 nm is formed. The amorphous silicon active layer 13 is formed on the gate 11 in the TFT region of the display substrate by patterning processes comprising exposure with a mask, development, etch, and lifting off.

S12, as shown in FIG. 3, the protection insulating layer 14 is formed on the structure resulting from S11. The protection insulating layer 14 comprises the first pattern 141 in the non-TFT region 30 and the second pattern 142 in the channel region of the amorphous silicon active layer 13.

In particular, an insulating film with a thickness of 40 nm-60 nm is deposited by PECVD, on the substrate 01 on which the amorphous silicon active layer 13 has been formed. Then, the first pattern 141 in the non-TFT region 30 and the second pattern 142 in the channel region are formed, by patterning processes comprising exposure with a mask, development, etch, and lifting off. For example, the protection insulating layer 14 of silicon dioxide (SiO₂) with a thickness of about 50 nm is formed. In other embodiments, the protection insulating layer 14 comprises silicon nitride (SiₓN_{y}) or silicon oxynitride (SiOₓN_{y}).

A side wall of the amorphous silicon active layer 13 can be well controlled during dry etching, so that the resulting active layer has an improved performance. Thus, in embodiments of the present disclosure, the insulating film is etched for example by dry etching.

As for the dry etching, for example plasma etching, reactive ion etching (RIE), inductively coupled plasma (ICP) etching or the like can be used. As for an etching gas, for example a fluorine or chlorine containing gas can be used. For example, CF₄, CHF₃, SF₆, CCl₂F₂, or a mixture of these gases with oxygen (O₂) can be used.

S13, as shown in FIGS. 4 and 5, an ohmic contact transitional pattern of e.g., n⁺ amorphous silicon is formed in the TFT region on the structure resulting from S12. The ohmic contact transitional pattern has a same shape as that of the amorphous silicon active layer 13.

In particular, as shown in FIG. 4, an n⁺ amorphous silicon film 151 with a thickness of 40 nm-70 nm is deposited by PECVD on the substrate 01 on which the protection insulating layer 14 has been formed. An n⁺ amorphous silicon transitional pattern 152 shown in FIG. 5 is formed by patterning processes comprising exposure with a mask, development, etch, and lifting off. For example, the n⁺ amorphous silicon transitional pattern 152 with a thickness about 50 nm is formed.

Since the n⁺ amorphous silicon transitional pattern 152 has a same shape as that of the amorphous silicon active layer 13, a mask for forming the amorphous silicon active layer 13 can be used in step S13.

In addition, for example, the n⁺ amorphous silicon film 151 is etched by dry etching.

S14, as shown in FIGS. 6-8, the source 16 and the drain 17 are formed on the structure resulting from S13. The n⁺ amorphous silicon transitional pattern 152, the first pattern 141 and the second pattern 142 are etched. The etched n⁺ amorphous silicon transitional pattern 152 forms the n⁺ amorphous silicon ohmic contact layer 15, and the second pattern 142 with a partially retained thickness forms the protection insulating layer pattern 143.

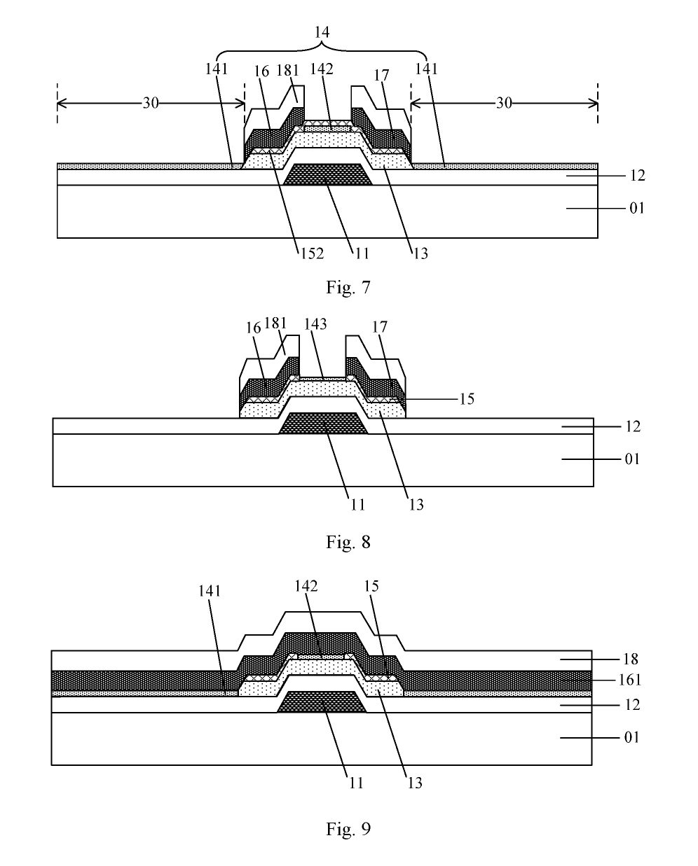

In particular, as shown in FIG. 6, a metal film 161 with a thickness of 100 nm-700 nm is deposited by magnetron sputtering on the substrate 01 on which the n⁺ amorphous silicon transitional pattern 152 has been formed. For example, the metal film 161 with a thickness about 250 nm is formed. The, a photoresist 18 with a thickness of 1.5 μm is coated on the metal film 161. The metal film generally comprises Mo, Al, Al—Ni alloy, Mo—W alloy, Cr, Cu, or a combination thereof. Then, the source 16 and the drain 17 shown in FIG. 7 are formed on the TFT region of the display substrate, by patterning processes comprising exposure with a mask, development, etch, and lifting off. For example, the metal film 161 is etched by wet etching.

Of course, in case the display substrate is an array substrate, for example, data lines are formed at a same time as forming the source 16 and the drain 17.

Furthermore, as shown in FIG. 8, the n⁺ amorphous silicon transitional pattern 152, the first pattern 141, and the second pattern 142 are etched. The etched n⁺ amorphous silicon transitional pattern 152 forms the n⁺ amorphous silicon ohmic contact layer 15, and the second pattern 142 with a partially retained thickness forms the protection insulating layer pattern 143. Then, a retained portion of photoresist 181 on the source 16 and the drain 17 is removed, to form the display substrate shown in FIG. 1a.

For example, the n⁺ amorphous silicon transitional pattern 152, the first pattern 141, and the second pattern 142 are etched by dry etching.

It is noted that, prior to the n⁺ amorphous silicon transitional pattern 152, the first pattern 141, and the second pattern 142 are etched, the second pattern 142 is shielded by the n⁺ amorphous silicon transitional pattern 152, while there is no shielding on the first pattern 141, as shown in FIG. 7. Thus, by selecting an etching gas which is capable of etching both the n⁺ amorphous silicon and the material for the first pattern 141 and the second pattern 142, and appropriately setting thicknesses of the n⁺ amorphous silicon transitional pattern 152, the first pattern 141 and the second pattern 142, the n⁺ amorphous silicon on the second pattern 142 can be etched away, the first pattern 141 can also be completely etched away, while the thickness of the second pattern 142 is partially retained to form the protection insulating layer pattern 143.

SiO₂, SiₓN_{y}, and SiOₓN_{y} are excellent insulating materials with a low cost. Thus, in embodiments of the present disclosure, the first pattern 141 and the second pattern 142 for example comprises at least one of SiO₂, SiₓN_{y}, and SiOₓN_{y}. Namely, the protection insulating layer 14 comprises at least one of SiO₂, SiₓN_{y}, and SiOₓN_{y}.

On basis of this, in the above step S14, the n⁺ amorphous silicon transitional pattern 152, the first pattern 141 and the second pattern 142 are etched, by dry etching in a mixture comprising e.g., SF₆ and O₂.

By taking SiO₂ as an example, in the mixture comprising SF₆ and O₂, an etching rate of silicon is larger than that of SiO₂. Thus, n⁺ amorphous silicon on the second pattern 142 is etched away quickly, until the first pattern 141 of SiO₂ is completely etched away and the etching process is stopped. At this time, a partial thickness of SiO₂ in the second pattern 142 is etched away, and the remaining thickness of SiO₂ is retained to form the protection insulating layer pattern 143.

Of course, a mixture comprising Cl₂ and O₂, or a mixture comprising CF₄ and O₂ has a similar effect as the mixture comprising SF₆ and O₂, which are not repeated here for simplicity. In these mixtures, SiₓN_{y} and SiOₓN_{y} also have a same effect as SiO₂.

On basis of this, for example, the thickness of n⁺ amorphous silicon is set to be equal to or slightly larger than that of the first pattern 141. As a result, when the first pattern 141 is etched away, n⁺ amorphous silicon has been etched away. The first pattern 141 and the second pattern 142 have a same thickness.

In embodiments of the present disclosure, the n⁺ amorphous silicon transitional pattern 152, the first pattern 141 and the second pattern 142 are etched by dry etching in the mixture comprising SF₆ and O₂, the mixture comprising Cl₂ and O2, or the mixture comprising CF₄ and O2. In this way, the process for forming the protection insulating layer pattern 143 can be easily controlled.

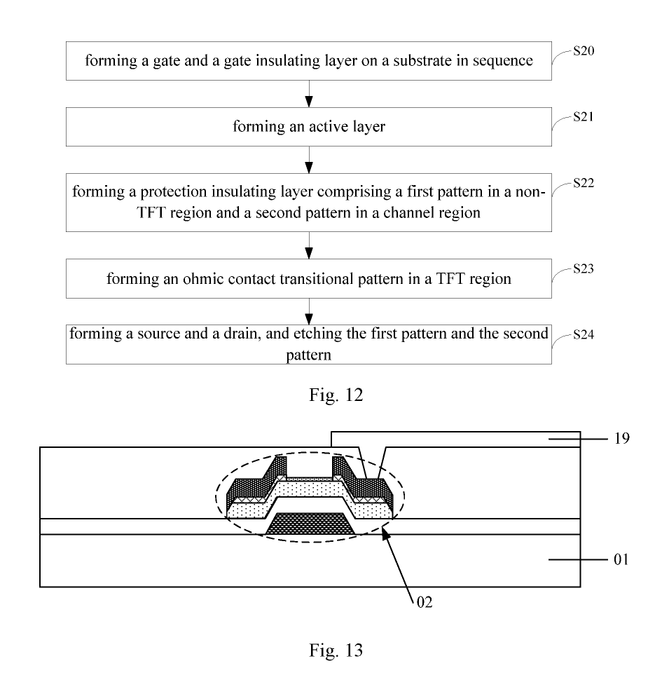

The method for fabricating a display substrate will be described hereinafter with reference to another embodiment. As shown in FIG. 12, forming the display substrate for example comprises the following steps.

S20, as shown in FIG. 3, the gate 11 and the gate insulating layer 12 are formed on the substrate 01 in sequence.

S21, as shown in FIG. 3, the active layer 13 of e.g., amorphous silicon is formed on the structure resulting from S20.

S22, as shown in FIG. 3, the protection insulating layer 14 comprising the first pattern 141 in the non-TFT region 30 and the second pattern 142 in the channel region is formed on the structure resulting from S21, form the protection insulating layer 14.

S23, as shown in FIG. 9, the n⁺ amorphous silicon ohmic contact layer 15 is formed on the structure resulting from S22 in the TFT region.

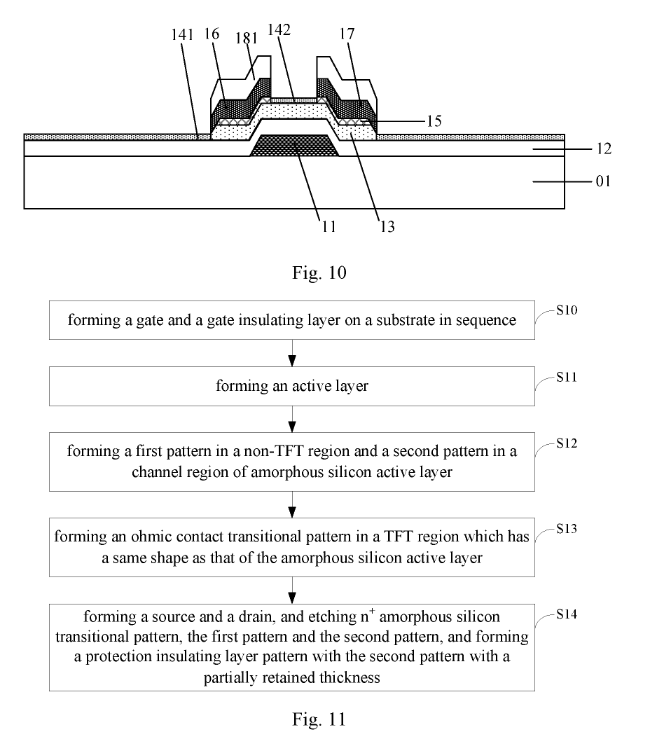

S24, as shown in FIGS. 9-10, the source 16 and the drain 17 are formed on the structure resulting from S23, and the first pattern 141 and the second pattern 142 are etched to form the display substrate shown in FIG. 2.

Here, as shown in FIG. 9, for example, the metal film 161 is deposited on the substrate 01 on which the n⁺ amorphous silicon ohmic contact layer 15 has been formed, and the photoresist 18 is coated on the metal film 161. Then, the source 16 and the drain 17 shown in FIG. 10 are formed on the TFT region of the display substrate, by patterning processes comprising exposure with a mask, development, etch, and lifting off.

Furthermore, as shown in FIG. 2, the first pattern 141 and the second pattern 142 are etched. Then, the retained portion of photoresist 181 on the source 16 and the drain 17 is removed.

Here, since the first pattern 141 and the second pattern 142 have a same thickness, both the first pattern 141 and the second pattern 142 are etched away.

On basis of this, as shown in FIG. 2, after the first pattern 141 is etched and removed, for example, the amorphous silicon active layer 13 below the first pattern 141 is overetched appropriately, so that electrically conductive particles accumulated on the surface of the amorphous silicon active layer 13 is prevented from penetrating the channel.

Embodiments of the present disclosure further provide a display substrate, as shown in FIG. 1a and FIG. 1b, comprising the TFT 02 which is arranged on the substrate 01. The TFT 02 comprises the gate 11, the gate insulating layer 12, the amorphous silicon active layer 13, the n⁺ amorphous silicon ohmic contact layer 15, the source 16, and the drain 17 which are arranged on the substrate 01 in sequence. The display substrate further comprises the protection insulating layer pattern 143 which is arranged on a side of the amorphous silicon active layer 13 away from the substrate 01, and is arranged in the channel region.

In embodiments of the present disclosure, the protection insulating layer 14 for example can be made from any suitable material which does not affect the channel region.

Embodiments of the present disclosure provide a display substrate. After forming the amorphous silicon active layer 13, and prior to forming the n⁺ amorphous silicon ohmic contact layer 15, the protection insulating layer 14 comprising the first pattern 141 in the non-TFT region 30 and the second pattern 142 in the channel region is formed. For example, during forming the n⁺ amorphous silicon ohmic contact layer 15, the first pattern 141 is completely removed, and the thickness of the second pattern 142 is partially retained to form the protection insulating layer pattern 143. On one hand, this ensures that the gate insulating layer 12 is kept intact, the damage to the gate insulating layer 12 is avoided, and the performance of the display substrate is ensured. On the other hand, the protection insulating layer pattern 143 is formed on the channel region, which prevents external electrically conductive particles from polluting the channel, and reduces the leakage current of the TFT 02.

For example, the protection insulating layer pattern has a thickness of 5-15 nm.

In embodiments of the present disclosure, the thickness of the protection insulating layer pattern 143 is set to 5-15 nm. On one hand, this thickness is sufficient to prevent external electrically conductive particles from polluting the channel. On the other hand, the thickness of 5-15 nm is negligible, and thus avoids effects on an overall thickness of the display substrate.

SiO₂, SiₓN_{y}, and SiOₓN_{y} are excellent insulating materials with a low cost. Thus, the protection insulating layer pattern for example comprises at least one of SiO₂, SiₓN_{y}, and SiOₓN_{y}.

For example the display substrate is an array substrate.

This avoids a deviation of a liquid crystal capacitance and a storage capacitance from a simulated result due to the damage to the gate insulating layer 12, and thus avoids problems of image flickering, as well as deviations of parameters like a coupling voltage, response time, and charging ratio.

As shown in FIG. 13, the array substrate further comprises a pixel electrode 19 which is electrically connected with the TFT 02.

Furthermore, the array substrate for example further comprises a common electrode.

As for an IPS (In-Plane Switching) array substrate, the pixel electrode and the common electrode are arranged in a same layer and spaced apart from each other, and both electrodes are strip shaped electrodes. As for an ADS (Advanced-super Dimensional Switching) array substrate, the pixel electrode and the common electrode are arranged in different layers, in which the upper electrode is a strip shaped electrode, and the lower electrode is a plate shaped electrode.

Embodiments of the present disclosure further provide a display panel, comprising the above display substrate.

In addition, embodiments of the present disclosure further provide a display device, which comprises the above display panel.

The display device for example is any product or component with a display function, such as a liquid crystal display, a liquid crystal TV, a digital photo frame, a mobile phone, a tablet computer.

Embodiments of the present disclosure provide a display substrate, a method for fabricating the same, and a display panel. After forming the amorphous silicon active layer, and prior to forming the n⁺ amorphous silicon ohmic contact layer, the protection insulating layer comprising the first pattern in the non-TFT region and the second pattern in the channel region is formed. During forming the n⁺ amorphous silicon ohmic contact layer, the gate insulating layer is maintained intact. This prevents damage to the gate insulating layer, and the performance of the display substrate is ensured. Since the material of the protection insulating layer is an insulating material, this prevents the channel region of the amorphous silicon active layer (i.e., a portion of amorphous silicon active layer corresponding to the gap between the source and the drain) from being polluted, and the performance of TFT is ensured.

Apparently, the person with ordinary skill in the art can make various modifications and variations to the present disclosure without departing from the spirit and the scope of the present disclosure. In this way, provided that these modifications and variations of the present disclosure belong to the scopes of the claims of the present disclosure and the equivalent technologies thereof, the present disclosure also intends to encompass these modifications and variations.

1. A method for fabricating a display substrate, comprising forming a TFT on a substrate,
wherein forming the TFT comprises forming a gate, a gate insulating layer, an active layer, an ohmic contact layer, a source and a drain on the substrate in sequence,
wherein after forming the active layer, and prior to forming the ohmic contact layer, the method further comprises forming a first pattern in a non-TFT region which is configured to cover the gate insulating layer.

2. The method of claim 1, further comprising: forming a second pattern in a channel region of the active layer by using a same insulating material as the first pattern and at a same time as forming the first pattern in the non-TFT region.

3. The method of claim 2, wherein at a same time as forming the ohmic contact layer, partially etching the second pattern to partially retain a thickness of the second pattern and form a protection insulating layer pattern.

4. The method of claim 3, wherein the protection insulating layer pattern has a thickness of 5-15 nm.

5. The method of claim 3, wherein forming the ohmic contact layer, the protection insulating layer pattern, the source and the drain comprises:
forming the first pattern and the second pattern on the substrate on which the active layer has been formed;
forming an ohmic contact transitional pattern on the substrate on which the first pattern and the second pattern have been formed, wherein the ohmic contact transitional pattern has a same shape as the active layer; and
forming the source and the drain on the substrate on which the ohmic contact transitional pattern has been formed, and etching the ohmic contact transitional pattern, the first pattern and the second pattern to form the ohmic contact layer and the protection insulating layer pattern.

6. The method of claim 5, wherein the first pattern is etched away, or the first pattern is etched to a thickness smaller than that of the protection insulating layer pattern.

7. The method of claim 2, wherein after forming the first pattern and the second pattern, the method further comprises:
forming an ohmic contact transitional pattern on the substrate on which the first pattern and the second pattern have been formed, wherein the ohmic contact transitional pattern is arranged in a source region and a drain region of the TFT region; and
forming the source and the drain on the substrate on which the ohmic contact transitional pattern has been formed.

8. The method of claim 7, wherein after forming the source and the drain, the method further comprises: etching the first pattern and the second pattern to have a same thickness.

9. The method of claim 8, wherein both the first pattern and the second pattern are etched away.

10. The method of claim 2, wherein the active layer is formed by amorphous silicon, and the ohmic contact layer is formed by n⁺ amorphous silicon.

11. The method of claim 10, wherein the insulating material comprises at least one of SiO₂, SiₓN_{y}, and SiOₓN_{y}.

12. The method of claim 11, wherein the ohmic contact transitional pattern, the first pattern and the second pattern are etched by dry etching in a mixture comprising SF₆ and O₂, Cl₂ and O₂, or CF₄ and O₂.

13. A display substrate, comprising a TFT which is arranged on a substrate, wherein the TFT comprises a gate, a gate insulating layer, an active layer, an ohmic contact layer, a source and a drain which are arranged on the substrate in sequence; and the TFT comprises a protection insulating layer pattern which is arranged on a side of the active layer away from the substrate, and which is arranged in a channel region.

14. The display substrate of claim 13, wherein the protection insulating layer pattern has a thickness of 5-15 nm.

15. The display substrate of claim 13, wherein the active layer is formed by amorphous silicon, and the ohmic contact layer is formed by n⁺ amorphous silicon.

16. The display substrate of claim 15, wherein the protection insulating layer pattern comprises at least one of SiO₂, SiₓN_{y}, and SiOₓN_{y}.

17. The display substrate of claim 13, wherein the display substrate is an array substrate.

18. A display panel, comprising the display substrate of claim 13.
